(19) United States
(12) Patent Application Publication
(10) Pub. No.: US 2009/0128991 A1
(43) Pub. Date: May 21, 2009

(54) Methods and apparatuses for stacked capacitors for image sensors

(75) Inventor: Richard A. Mauritzson, Meridian, ID (US)

Correspondence Address: DICKSTEIN SHAPIRO LLP, 1825 EYE STREET, NW, WASHINGTON, DC, 20006, US

(73) Assignee: Micron Technology, Inc.

(21) Appl. No.: 11/984,778

(22) Filed: Nov. 21, 2007

(51) Int. Cl. H01G 4/38; H01L 21/20

(52) U.S. Cl. 361/328; 438/396; 257/E21.113

(57) ABSTRACT

Capacitive circuits and methods of forming capacitive circuits including a first capacitor and a second capacitor connected in parallel to the first capacitor, wherein the first capacitor is positioned at least partially above the second capacitor.

### FIELD OF THE INVENTION

Disclosed embodiments relate generally to the field of image sensors employing capacitors.

### BACKGROUND OF THE INVENTION

The constant drive for higher resolution, higher pixel density image sensors has pushed the pixel size, and thus the row/column pitch, of the pixel array to the point where column readout circuitry is being constrained to fit within the required pitch.

FIG. 1 illustrates, in a simplified block diagram, an imaging device 100 having a CMOS pixel array 140. Row lines of the array 140 are selectively activated by a row driver 145 in response to row address decoder 155. A column driver 160 and column address decoder 170 are also included in the imaging device 100. The imaging device 100 is operated by the timing and control circuit 150, which controls the address decoders 155, 170. The control circuit 150 also controls the row and column driver circuitry 145, 160.

A sample and hold circuit 200 associated with the column driver 160 samples and holds a pixel reset signal Vrst and a pixel image signal Vsig for each selected pixel of the array 140. A differential signal (Vrst−Vsig) is produced by differential amplifier 162 for each pixel and is digitized by analog-to-digital converter 175 (ADC). In some designs, a respective sample and hold circuit and differential amplifier are provided for each column of the array 140. The analog-to-digital converter 175 supplies the digitized pixel signals to an image processor 180, which forms and may output a digital image.

FIG. 2 is a schematic diagram of a known sample and hold circuit 200, which is provided in association with a respective column line 201. The illustrated sample and hold circuit 200 includes a load transistor 202 that receives a signal (VLN) at its gate. As is known in the art, the VLN signal activates the load transistor 202 such that it provides a current path and load on the column line 201 which is connected to a column of pixels in array 140 (FIG. 1). The column line 201 is further coupled to two sample and hold capacitors 206, 207. The first capacitor 206 stores a reset signal value (Vrst) when a first sample-and-hold signal (SHR) is applied to a first switch 203. The second capacitor 207 stores a pixel signal value (Vsig) when a second sample-and-hold signal (SHS) is applied to a second switch 204. Sampling both the reset and pixel signal voltage levels allows correlated double sampling (CDS) to be performed, which can reduce noise associated with the connected pixel as well as noise associated with the source-follower circuitry in the pixel circuit.

Sample and hold capacitors 206, 207 can be held at a reference voltage (VCL) by closing first and second reference switches 208, and 209, respectively. The signal clampR controls the state of switch 209, and the signal clampS controls the state of switch 208. This operation helps store the reset and pixel signal values into the capacitors 206, 207.

In addition, the sample and hold circuit 200 typically includes a crowbar switch 205. The state of the crowbar switch 205 is controlled by an external crowbar control signal (CB). The crowbar switch 205 is used during reset of the signals stored in the capacitors 206, 207. Use of the crowbar switch 205 can help reduce fixed pattern noise (FPN) caused by column-to-column variations due to the column parallel readout structure.

Signals stored by the sample and hold capacitors 206, 207 can be transmitted to the differential amplifier 162 (FIG. 1) through respective column select switches 210, 211. The column selection signal (ColSel) controls the column select switches 210, 211. When the column selection switches 210, 211 are turned on, the sample and hold capacitors 206, 207 are coupled directly to respective inputs of differential amplifier 162 which receives the stored Vrst and Vsig signals.

In order to increase the charge storage capacity, i.e., capacitance, of sample and hold capacitors 206, 207, it is generally necessary to increase the size of the individual capacitors. FIG. 3A is a circuit diagram of a conventional single sample and hold capacitor 300, which is typically used for each of the sample and hold capacitors 206, 207. The sample and hold capacitor 300 includes top and bottom plates 301, 302 and a dielectric layer 303. As the column pitch of the array becomes smaller to support higher density resolutions, the space available for the sample and hold capacitors becomes constrained, and it becomes difficult to maintain the required capacitance within the given space, or without increasing die size in the column direction. In order to increase, or even to maintain, the charge holding capacity, the storage capacity of the capacitor 300 must be increased.

One way to increase the electrical size of the capacitor 300 is to use two side-by-side capacitors in the column direction connected in parallel. FIG. 3B is a circuit diagram of consisting of two conventional capacitors 310, 320 connected in this configuration, each having a capacitance of C. The total capacitance of the two capacitors 310, 320 together is C+C=2C. Each of the capacitors 310, 320 includes respective top plates 311, 321, bottom plates 312, 322, and dielectric layers 313, 323. Each capacitor 310, 320 is formed of the same set of materials. The two-capacitor configuration still reduces space available for other imager components within the required column pitch because the two capacitors 310, 320 each take up lateral space in the imager.

Accordingly, there is a need and desire for capacitors having higher capacitance while decreasing space required for readout circuitry and increasing fill factor.

### BRIEF DESCRIPTION OF THE DRAWINGS

FIG. 1 is a block diagram of an imaging device.

FIG. 2 is a schematic diagram of a sample and hold circuit.

FIG. 3A is a circuit diagram of a single sample and hold capacitor.

FIG. 3B is a circuit diagram of two capacitors connected in parallel.

FIG. 3C is a top-down view of the two capacitors of FIG. 3B.

FIG. 4A is a circuit diagram of a capacitive circuit including a multi-layer sample and hold capacitor constructed in accordance with an embodiment described herein.

FIG. 4B is a flowchart of a process for forming a capacitive circuit including a multi-layer sample and hold capacitor in accordance with an embodiment described herein.

FIG. 4C is a cross-sectional view of a capacitive circuit including a multi-layer sample and hold capacitor constructed in accordance with an embodiment described herein.

FIG. 4D is a cross-sectional view of a capacitive circuit including a multi-layer sample and hold capacitor constructed in accordance with another embodiment described herein.

FIG. 5 is a cross-sectional view of an integrated circuit capacitive circuit including a multi-layer sample and hold capacitor constructed in accordance with an embodiment described herein.

FIG. 6 is a cross-sectional view of an integrated circuit capacitive circuit including a multi-layer sample and hold capacitor constructed in accordance with an embodiment described herein.

FIG. 7A is a cross-sectional view of a first capacitor constructed in accordance with an embodiment described herein.

FIG. 7B is a cross-sectional view of a first capacitor constructed in accordance with another embodiment described herein.

FIG. 7C is a flowchart of a process for forming a first capacitor in accordance with an embodiment described herein.

FIG. 8 is an embodiment of a camera system that can be used with the FIG. 1 imaging device constructed in accordance with an embodiment described herein.

### DETAILED DESCRIPTION OF THE INVENTION

In the following detailed description, reference is made to the accompanying drawings, which form a part hereof and show by way of illustration specific embodiments in which embodiments of the present invention may be practiced. These embodiments are described in sufficient detail to enable those skilled in the art to practice them, and it is to be understood that other embodiments may be utilized, and that structural, logical, processing, and electrical changes may be made. The progression of processing steps described is an example; however, the sequence of steps is not limited to that set forth herein and may be changed as is known in the art, with the exception of steps necessarily occurring in a certain order.

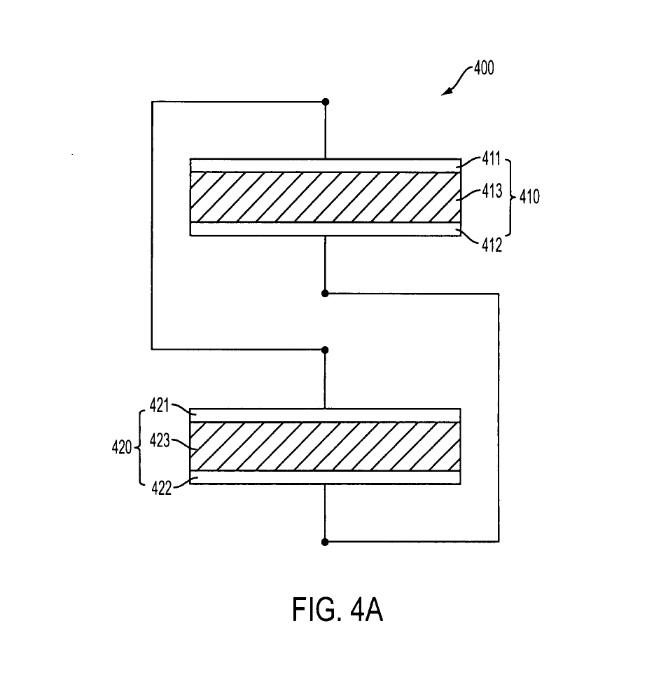

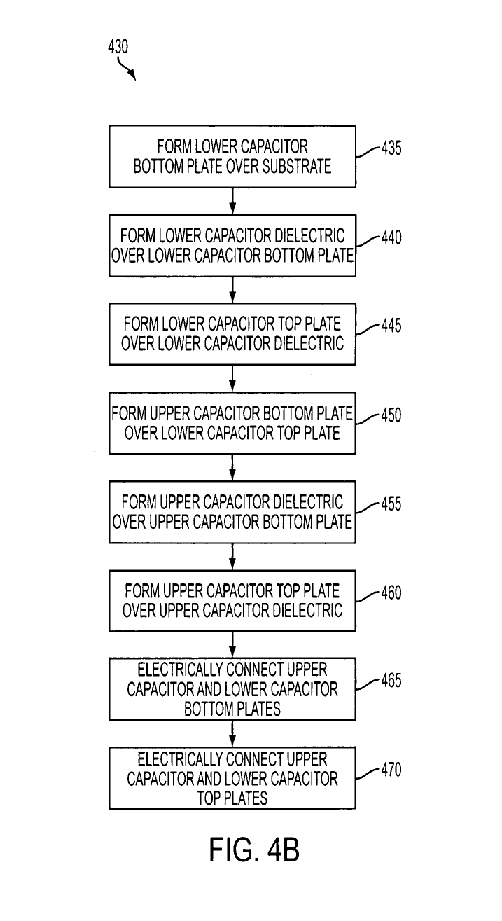

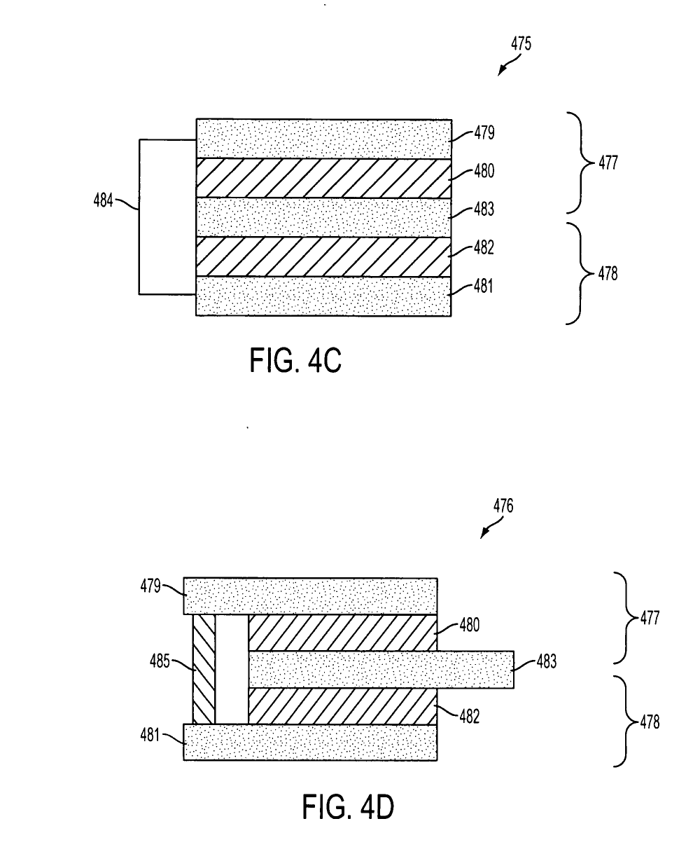

Now referring to the figures, where like numerals designate like elements, FIG. 4A is a circuit diagram of a capacitive circuit including a multi-layer sample and hold capacitor 400 constructed in accordance with an embodiment described herein. The multi-layer sample and hold capacitor 400 includes first and second capacitors 410, 420, each having a capacitance of C, which are coupled in parallel. First and second capacitors 410, 420 are arranged such that first capacitor 410 is positioned at least partially above second capacitor 420 in a “stacked” configuration. The total capacitance of the two capacitors 410, 420 together is C+C=2C. Each of the capacitors 410, 420 includes respective top plates 411, 421, bottom plates 412, 422, and dielectric layers 413, 423. The two capacitors 410, 420 (which make up the sample and hold capacitor 400) may be formed of the same set of materials, or each of a different set of materials, as dictated by the application.

The multi-layer sample and hold capacitor 400 includes first and second capacitors 410,420 which are coupled in parallel. Each of the capacitors 410,420 includes top and bottom plates 411, 412, 421, 422, formed of metal or doped polysilicon. Embodiments further include top plates 411, 421 of polysilicon and bottom plates 412, 422 of metal, or vice versa. The first and second capacitors 410, 420 will be separated by an insulating material (not shown) between top plate 421 and bottom plate 412. Additional embodiments include using different types of polysilicons or metals. Capacitors having polysilicon top and bottom plates are known in the art as “poly-poly” capacitors. Capacitors having metal top and bottom plates are known in the art as “metal-insulator-metal” or “MIM” capacitors. Capacitors having one polysilicon and one metal plate are known in the art as “poly-insulator-metal” or “PIM” capacitors.

Embodiments include any appropriate metal for any of the top and bottom plates 411, 412, 421, 422, although specific embodiments include copper, aluminum, tungsten, and tantalum. Embodiments further include any appropriate polysilicon material for top and bottom plates 411, 412, 421, 422. Additional embodiments include any appropriate dielectric material for dielectric layers 413, 423, although specific embodiments include a nitride or an oxide as a dielectric material. There will also be an insulation layer (omitted for clarity) between bottom plate 412 and top plate 421. The size of each capacitor 410, 420 may be selected to achieve the desired capacitances.

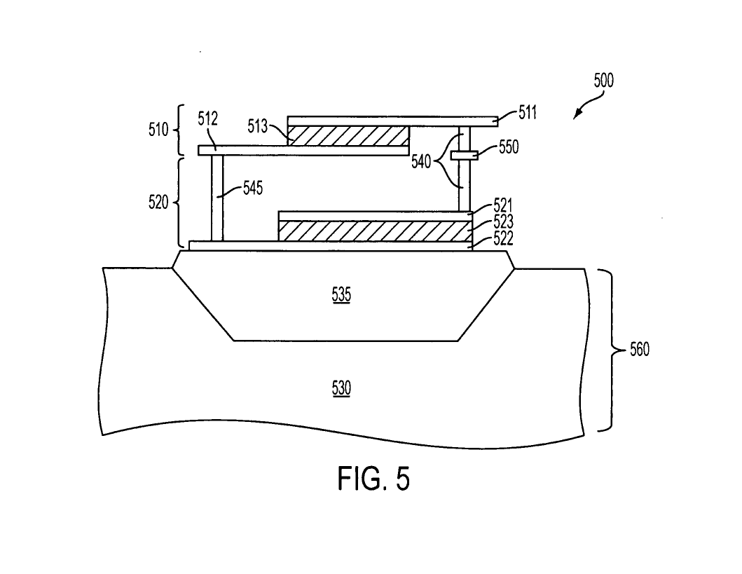

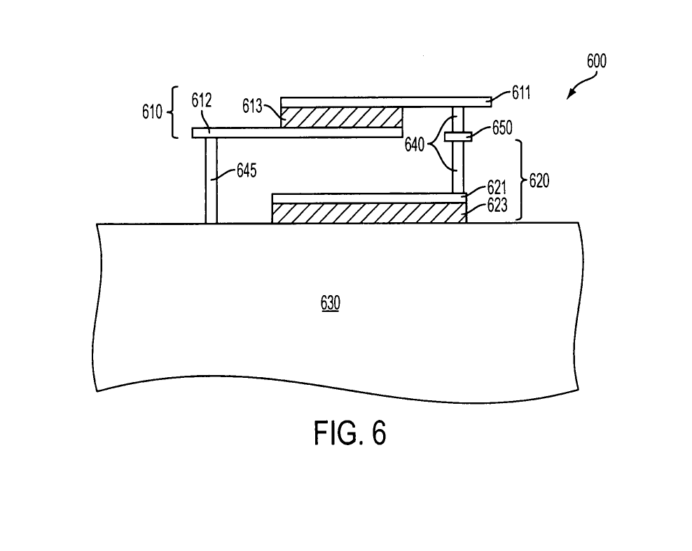

FIG. 4B is a flowchart of a process 430 for forming a capacitive circuit including a multi-layer sample and hold capacitor in accordance with an embodiment described herein. First the lower capacitor 420 is formed according to the following steps. At step 435, the lower capacitor 420 bottom plate 422 is formed over a substrate (e.g., substrate 530 in FIG. 5 or substrate 630 in FIG. 6, both described below). Next, the lower capacitor 420 dielectric 423 is formed over the lower capacitor 420 bottom plate 422 (step 440). At step 445, the lower capacitor 420 top plate 421 is formed over the lower capacitor 420 dielectric 423.

Then the upper capacitor 410 is formed according to the following steps. The upper capacitor 410 bottom plate 412 is formed over the lower capacitor 420 top plate 421 (step 450). At step 455, the upper capacitor 410 dielectric 413 is formed over the upper capacitor 410 bottom plate 412. Then, the upper capacitor 410 top plate 411 is formed over the upper capacitor 410 dielectric 413. Then the electrical connections are made between the respective top and bottom plates of the top and bottom capacitors (steps 465, 470). Steps 465 and 470 may be performed simultaneously or interchangeably.

FIG. 4C is a cross-sectional view of a capacitive circuit including a multi-layer sample and hold capacitor 475 constructed in accordance with an embodiment. FIG. 4D is a cross-sectional view of a capacitive circuit including a multi-layer sample and hold capacitor 476 constructed in accordance with another embodiment. Multi-layer sample and hold capacitors 475, 476 each include first and second capacitors 477, 478. Capacitor 477 includes a first plate 479 and a dielectric 480. Capacitor 478 includes a first plate 481 and a dielectric 482. First and second capacitors 477, 478 share a common second plate 483. Multi-layer sample and hold capacitor 475 includes a connector 484 which connects the first plates 479, 481. Multi-layer sample and hold capacitor 476 includes a metal connector 485 which connects the first plates 479, 481, where the first plates 479, 481 extend beyond the dielectrics 480, 482 and the common second plate 483.

FIG. 5 is a cross-sectional view of a capacitive circuit including a multi-layer sample and hold capacitor 500 constructed in accordance with an embodiment described herein. The multi-layer sample and hold capacitor 500 includes first and second capacitors 510, 520 which are coupled in parallel. Each of the capacitors 510, 520 includes respective top plates 511, 521, bottom plates 512, 522, and dielectric layers 513, 523. It should be appreciated that, although the dielectric layers 513, 523 are shown in FIG. 5 as terminating laterally with the respective top and bottom plates 511, 512, 521, 522, they may extend beyond the respective top plates 511, 521. The top plates 511, 521 are electrically connected by a first metal connector 540. The bottom plates 512, 522 are electrically connected by a second metal connector 545.

According to the illustrated embodiment, the second (bottom) capacitor 520 may be formed on an oxide layer 535 (such as shallow trench isolation (“STI”) or local oxidation of silicon (“LOCOS”)), which may be grown or deposited according to known methods. The oxide layer 535 may be formed on a substrate 530, typically of silicon. In addition, the bottom plate 522 of the second (bottom) capacitor 520 may be used with the oxide layer 535 and substrate 530 to provide additional capacitance (e.g., capacitor 560), if desired.

Embodiments include capacitors 510, 520 having top and bottom plates 511, 512, 521, 522, formed of the same or similar materials as respective plates described above with reference to FIG. 4A. If the first (top) capacitor 510 has a bottom plate 512 formed from a metal, an optional via 550 may be formed to connect portions of the first metal connector 540. The bottom plate 512 and the via 550 may be formed in the same layer. Similarly, if the top plate 521 of the second capacitor 520 is formed from a metal, an optional via (not shown) may be formed to connect portions of the second metal connector 545. There will also be an insulation layer (omitted for clarity) between bottom plate 512 and top plate 521.

FIG. 6 is a cross-sectional view of a capacitive circuit including a multi-layer of sample and hold capacitor 600 constructed in accordance with an embodiment described herein. The multi-layer sample and hold capacitor 600 includes first and second capacitors 610, 620 which are coupled in parallel. The first (upper) capacitor 610 is constructed similarly to the first capacitor 510 of FIG. 5, having a top plate 611, bottom plate 612, and dielectric layer 613. The second (lower) capacitor 620 includes a top plate 621 and dielectric layer 613, similar to the top plate 521 and dielectric layer 512 of the second capacitor 520 of FIG. 5. However, the second capacitor 620 uses the substrate 630, typically of silicon, as a bottom plate. There is no need for an additional oxide layer. Embodiments include capacitors 610, 620 having top plates 611, 621, dielectric layers 613, 623, and first capacitor 610 top plate 611 formed of the same or similar materials as respective plates described above with reference to FIG. 4A. There will also be an insulation layer (omitted for clarity) between bottom plate 612 and top plate 621. The bottom plate 612 and the via 650 may be formed in the same layer.

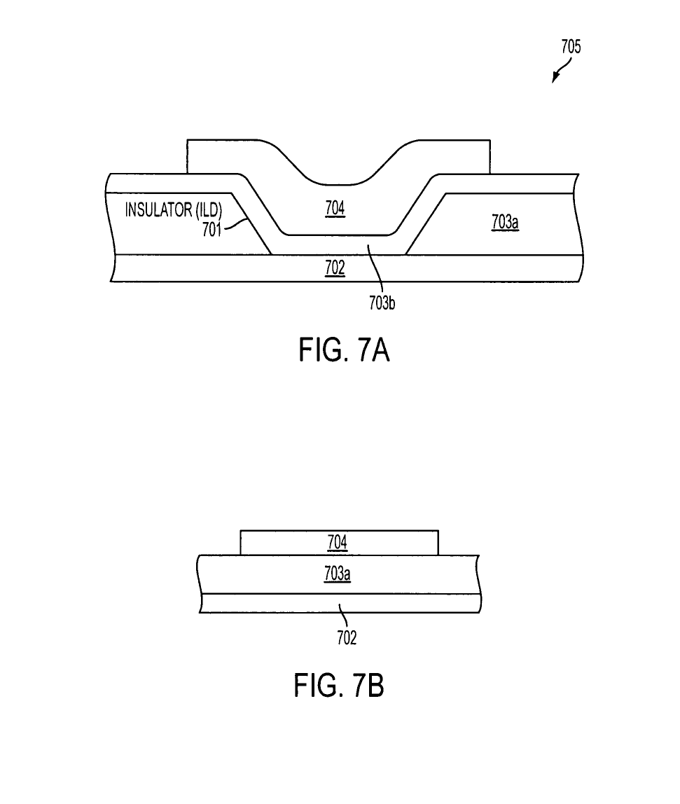

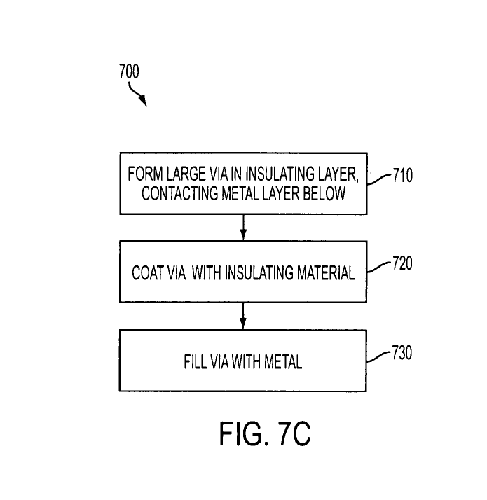

FIG. 7A is a schematic of a MIM capacitor 705 which may be used for the first (top) capacitor 410 in accordance with an embodiment. FIG. 7B is a cross-sectional view of the first capacitor 410 in accordance with another embodiment. FIG. 7C is a flowchart of a process 700 for forming the first capacitor 410 in accordance with an embodiment. A large via 701 may be formed in the insulator layer 703a (typically oxide or a low-K dielectric) above and connecting to metal layer 702 (step 710). The metal layer 702 creates the bottom plate 412. The interior of the via 701 is coated with a dielectric material 703b (step 720) to create the dielectric layer 413. Finally, the via 702 is filled with metal 704 (step 730), covering the dielectric material 703 to create the top plate 411. It should be noted that the insulating layer 703a could substitute as the capacitor dielectric, eliminating the need to form the large via 701 and deposition of dielectric layer 703b, as shown in FIG. 7B. Alternatively, either plate of capacitor 705 could include a polysilicon material to create a PIM capacitor instead.

For capacitors using polysilicon plates, such as poly-poly or PIM capacitors, embodiments include, but are not limited to, polysilicon plate thicknesses of 100 Å-5,000 Å. The polysilicon is typically a doped polysilicon, which may be in-situ doped or an implanted polysilicon. Nonlimiting examples of n-type polysilicon doping materials include phosphorus and arsenic. Embodiments further include, but are not limited to, insulator thicknesses between polysilicon layers of 10 Å-500 Å. Nonlimiting examples of insulator materials include hafnium oxide (HfO) and tantalum pentoxide (Ta₂O₅). Embodiments also include, but are not limited to, oxide layer thicknesses of 10 Å-500 Å, which may be formed from a furnace-based, chemical vapor deposition (CVD), or plasma enhanced chemical vapor deposition (PECVD) processes.

For capacitors using metal plates, such as MIM or PIM capacitors, embodiments include, but are not limited to, metal plate thicknesses of 500 Å-10,000 Å. Embodiments further include, but are not limited to, insulator thicknesses between metal layers of 50 Å-5,000 Å. Typically, although without limitation, thicknesses of up to 500 Å are used for the dielectric material between metal layers. Embodiments include chemical vapor deposition (CVD) or plasma enhanced chemical vapor deposition (PECVD) processes for forming the dielectric material between metal layers, as furnace-based processes can reflow or melt the metals.

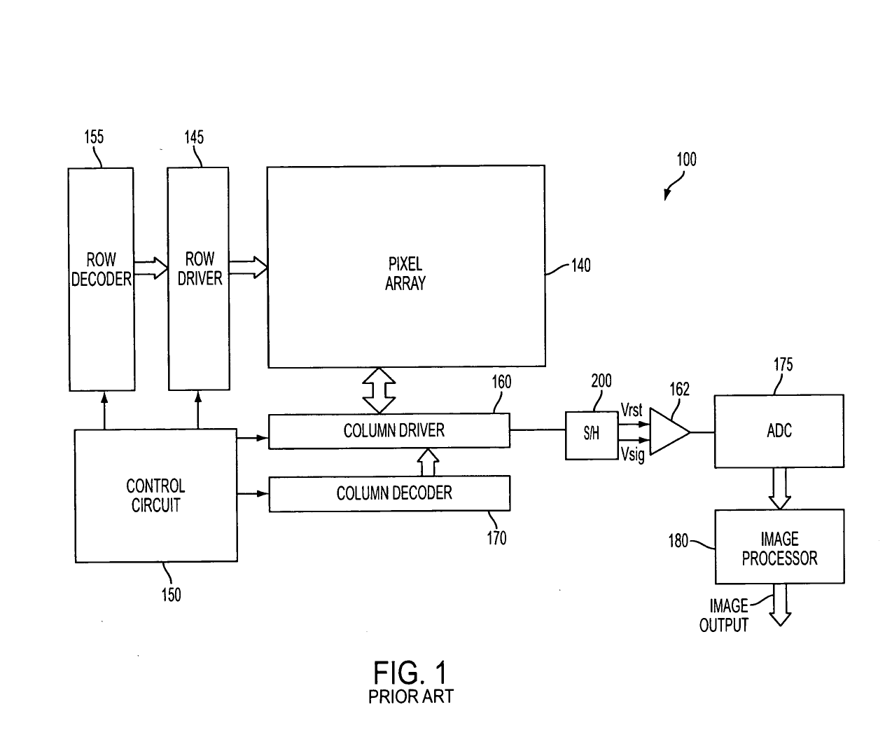

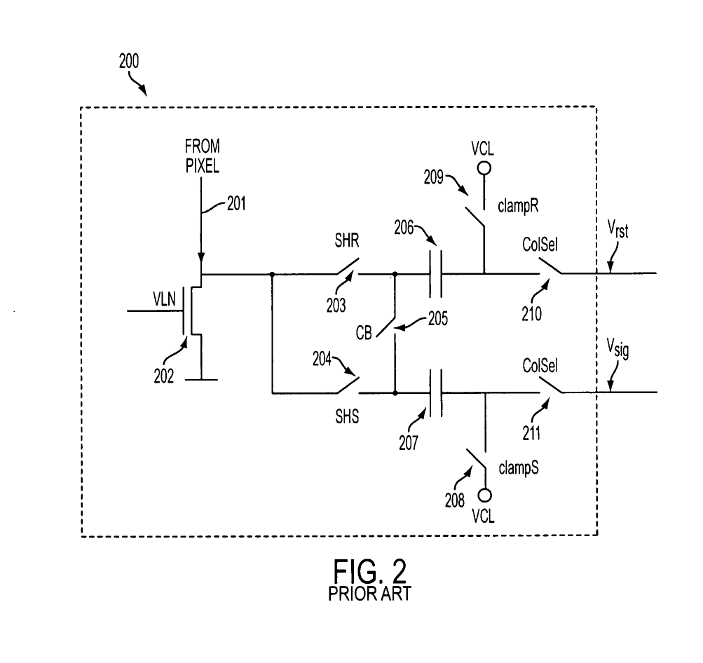

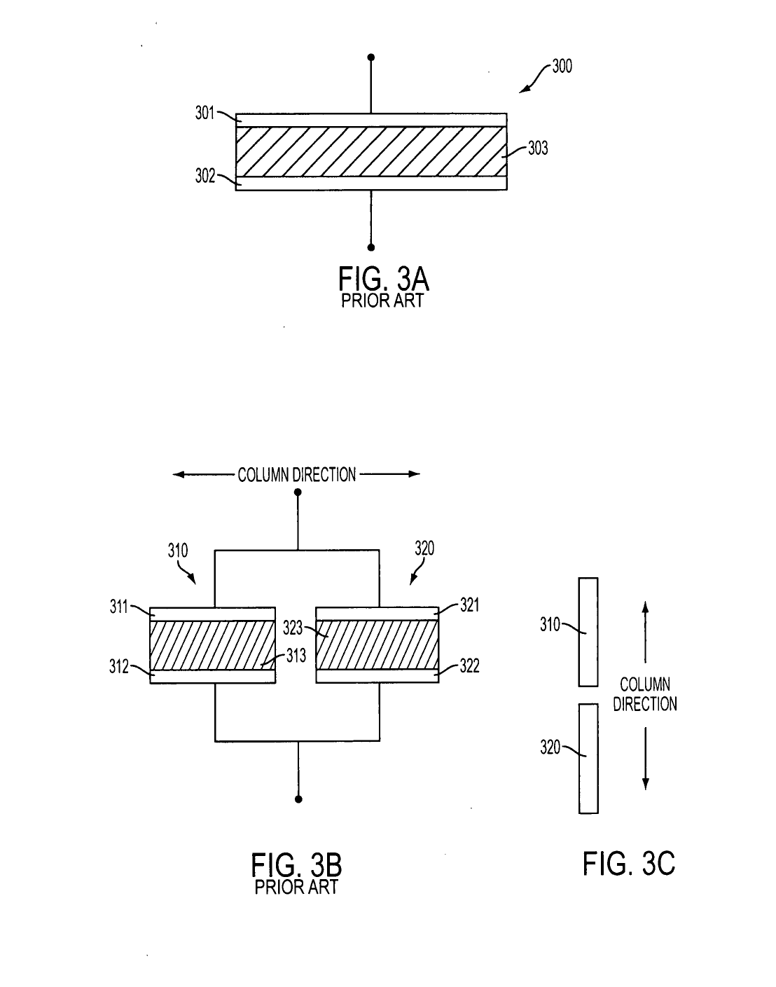

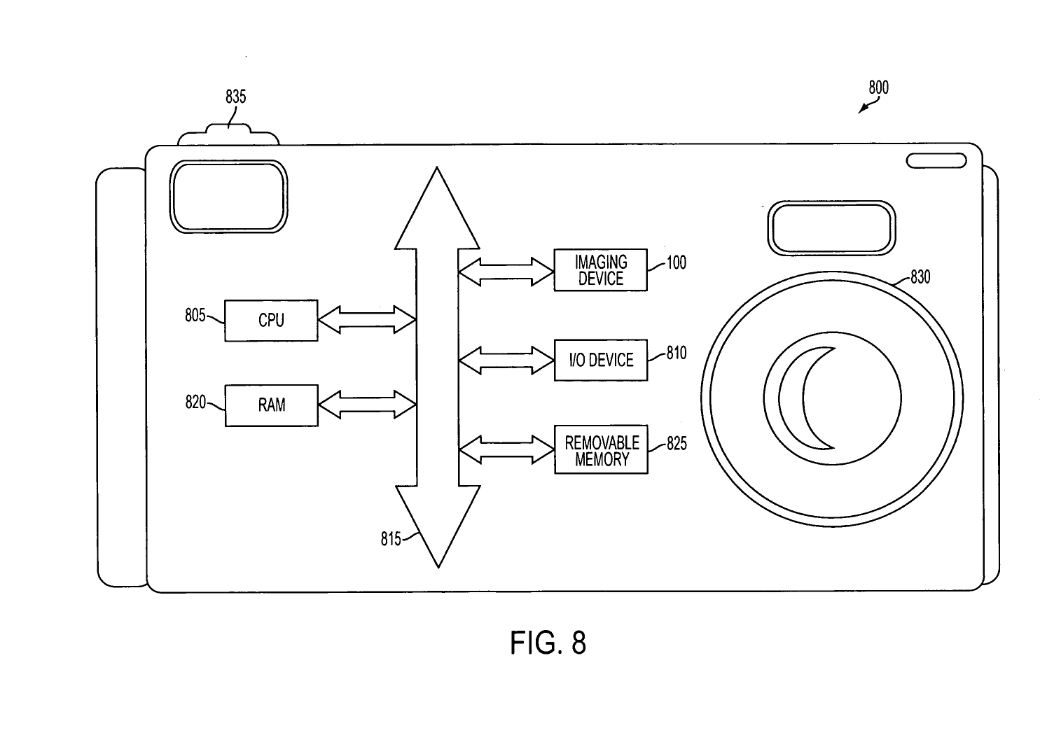

FIG. 8 is an embodiment of a camera system 800, which can use the FIG. 1 imaging device 100 constructed in accordance with an embodiment described herein, having a sample and hold circuit 200 capable of implementing at least one multi-layer capacitor 400, 500, 600, and/or at least one of processes 400 and 700. Camera system 800, for example, a still or video camera system, which generally comprises a lens 830 for focusing an image on the pixel array 140 (FIG. 1) when shutter release button 835 is depressed, a central processing unit (CPU) 805, such as a microprocessor for controlling camera operations, that communicates with one or more input/output (I/O) devices 810 over a bus 815. Imaging device 100 also communicates with the CPU 805 over bus 815. The system 800 also includes random access memory (RAM) 820, and can include removable memory 825, such as flash memory, which also communicate with CPU 805 over the bus 815. Imaging device 100 may be combined with a processor, such as a CPU, digital signal processor, or microprocessor, with or without memory storage on a single integrated circuit or on a different chip than the processor.

The camera system 800 is one example of a system having digital circuits that could include image sensor devices. Without being limiting, such a system could instead include a computer system, scanner, machine vision, vehicle navigation, video phone, surveillance system, auto focus system, star tracker system, motion detection system, image stabilization system, and other image acquisition and processing system.

The processes and devices in the above description and drawings illustrate examples of methods and devices of many that could be used and produced to achieve the objects, features, and advantages of embodiments described herein. For example, embodiments include employing a different capacitor type for each capacitor and/or different materials for each plate of a capacitor. Embodiments also include employing a same capacitor type for each capacitor and/or same materials for each plate of a capacitor. Same types with different materials may also be used. Embodiments further include the stacked capacitor configuration and formation used for applications other than sample and hold capacitors, and for other applications than an imaging device. In addition, the sample and hold capacitors may be formed in a integrated circuit, on a circuit board, or any other appropriate medium. Thus, the embodiments are not to be seen as limited by the foregoing description of the embodiments, but only limited by the appended claims.

What is claimed as new and desired to be protected by Letters Patent of the United States is:

1. A capacitive circuit comprising:
a first capacitor; and
a second capacitor electrically connected in parallel to the first capacitor,
wherein the first capacitor is positioned at least partially above the second capacitor.

2. The capacitive circuit of claim 1, wherein:
the first capacitor comprises one of: a poly-poly capacitor, a metal-insulator-metal (MIM) capacitor, and a poly-insulator-metal (PIM) capacitor; and
the second capacitor comprises one of: a poly-poly capacitor, a metal-insulator-metal (MIM) capacitor, and a poly-insulator-metal (PIM) capacitor.

3. The capacitive circuit of claim 1, wherein the first and second capacitors comprises the same type of capacitor materials.

4. The capacitive circuit of claim 1, wherein the first and second capacitors comprises different types of capacitor materials.

5. The capacitive circuit of claim 1, further comprising a third capacitor positioned at least partially below and electrically connected to the second capacitor.

6. The capacitive circuit of claim 1, wherein the capacitive circuit comprises a sample and hold circuit for an imaging device.

7. The capacitive circuit of claim 1, wherein:
the first capacitor comprises a first top plate, a first bottom plate, and a first dielectric material between the first top and bottom plates; and
the second capacitor comprises a second top plate, a second bottom plate, and a second dielectric material between the second top and bottom plates.

8. The capacitive circuit of claim 7, further comprising:
a substrate,
wherein the second capacitor is formed over the substrate.

9. The capacitive circuit of claim 8, wherein the substrate functions as a second bottom plate for the second capacitor.

10. The capacitive circuit of claim 7, wherein each of the first and second top and bottom plates comprises a polysilicon material or a metal material.

11. The capacitive circuit of claim 10, wherein the polysilicon material comprises a doped polysilicon material.

12. The capacitive circuit of claim 10, wherein the a metal material comprises one of: copper, aluminum, tungsten, and tantalum.

13. The capacitive circuit of claim 7, wherein the first and second dielectric materials each comprise an oxide material or a nitride material.

14. The capacitive circuit of claim 13, wherein the oxide material comprises hafnium oxide or tantalum tin oxide.

15. The capacitive circuit of claim 7, further comprising:
first and second metal connectors for electrically connecting the first and second capacitors in parallel.

16. The capacitive circuit of claim 15, further comprising a via for electrically connecting first and second portions of the first metal connector,
wherein the first bottom plate of the first capacitor comprises a metal material.

17. A capacitive circuit comprising:
a first capacitor; and
a second capacitor stacked over and electrically connected in parallel to the first capacitor.

18. An imaging device comprising:
a readout circuit, the readout circuit comprising:
a sample and hold circuit, the sample and hold circuit comprising:
the capacitive circuit of claim 17.

19. A camera comprising:
an imager, the imager comprising:
a sample and hold circuit, the sample and hold circuit comprising:
the capacitive circuit of claim 17.

20. A method of forming a capacitive circuit comprising:
forming a lower capacitor over a semiconductor substrate;
forming an upper capacitor positioned at least partially over the lower capacitor, the upper capacitor electrically connected in parallel to the lower capacitor.

21. The method of claim 20, wherein forming the upper capacitor comprises:
forming a first bottom plate over the lower capacitor;
forming a first dielectric layer over the first bottom plate; and
forming a first top plate over the first dielectric layer.

22. The method of claim 21, wherein forming the lower capacitor comprises:
forming a second dielectric layer over the substrate; and
forming a second top plate over the second dielectric layer.

23. The method of claim 22, wherein forming the lower capacitor further comprises:
forming a second bottom plate below the second dielectric layer; and
forming an oxide layer between the second bottom plate and the substrate.

24. The method of claim 20, further comprising:
forming first and second metal connectors for electrically connecting the first and second capacitors in parallel.

25. The method of claim 20, wherein forming the upper capacitor comprises:
forming a via in a metal layer;
coating an interior surface of the via with an dielectric material; and
filling the via with a metal material.
